(19) United States
(12) Patent Application Publication
(10) Pub. No.: US 2018/0329006 A1
(43) Pub. Date: Nov. 15, 2018

(54) DIFFUSION-RELAXATION CORRELATION SPECTROSCOPIC IMAGING

(71) Applicant: University of Southern California, Los Angeles, CA (US)

(72) Inventors: Justin Haldar, Los Angeles, CA (US); Daeun Kim, Los Angeles, CA (US)

(21) Appl. No.: 15/976,548

(22) Filed: May 10, 2018

Related U.S. Application Data
(60) Provisional application No. 62/503,836, filed on May 9, 2017.

(51) Int. Cl. G01R 33/44; G06T 7/32; G01R 33/54; G01R 33/46

(52) U.S. Cl. CPC G01R 33/443; G06T 7/32; G06T 2207/10088; G01R 33/46; G01R 33/543

(57) ABSTRACT

A method for identifying and spatially mapping microenvironments using coarse-resolution correlation spectroscopic imaging includes acquiring, using a magnetic resonance imaging (MRI) scanner, acquired data that includes high-dimensional contrast encoded data of a target for each of multiple voxels. The method also includes creating, using a signal processor, a model of the acquired data as a spatially-varying mixture of high dimensional real-valued exponential decays. The method also includes estimating, using the signal processor, a multidimensional correlation spectroscopic image that includes a multidimensional correlation spectrum at each of the multiple voxels.

### CROSS-REFERENCE TO RELATED APPLICATIONS

This application claims the benefit and priority of U.S. Provisional Application No. 62/503,836, entitled “Diffusion-Relaxation Correlation Spectroscopic Imaging,” filed on May 9, 2017, the entire disclosure of which is hereby incorporated by reference herein in its entirety.

### STATEMENT AS TO FEDERALLY SPONSORED RESEARCH

This invention was made with government support under contract numbers R01 NS089212 and R21 EB022951 awarded by the National Institute of Health (NIH) and contract number CCF1350563 awarded by the National Science Foundation (NSF). The government has certain rights in this invention.

### BACKGROUND

### 1. Field

The present disclosure relates to systems and methods for performing high dimensional correlation spectroscopic imaging of tissue using magnetic resonance imaging (MRI) scanners.

### 2. Description of the Related Art

Magnetic resonance imaging (MRI) is a medical imaging technique that is capable of forming images of the anatomy and physiological processes of tissue. MRI can be used to evaluate whether a given tissue is healthy or diseased. MRI scanners use several different magnetic fields (including static magnetic fields, oscillatory radio-frequency magnetic fields, and spatially varying gradient fields) to acquire data that can be reconstructed to yield images that can be used to evaluate the tissue.

Various types of MRI experiments are available. One such MRI technique is called diffusion MRI and utilizes the diffusion of MR-detectable nuclei (frequently the hydrogen nuclei from water molecules) to generate contrast in magnetic resonance (MR) images. Diffusion MRI allows the mapping of the diffusion process of molecules in biological tissue, in vivo, and non-invasively. Molecular diffusion in tissues is not free, but it reflects interactions with many obstacles, such as macromolecules, fibers, and membranes. Molecular diffusion patterns can therefore reveal microscopic details about tissue architecture.

Another MRI technique is called relaxation MRI. The term relaxation describes how magnetization that has been excited away from its equilibrium state will eventually return to equilibrium over time. The speed at which the system returns to equilibrium depends on features of the microscopic tissue environment, and therefore can also reveal microscopic information. By varying the parameters of the pulse sequence, different contrasts may be generated between tissues based on the relaxation properties of the nuclei therein.

### SUMMARY

Described herein is a method for identifying and spatially mapping microenvironments using coarse-resolution correlation spectroscopic imaging. The method includes acquiring, using a magnetic resonance imaging (MRI) scanner, acquired data that includes high-dimensional contrast encoded data of a target for each of multiple voxels. The method also includes creating, using a signal processor, a model of the acquired data as a spatially-varying mixture of high dimensional real-valued exponential decays. The method also includes estimating, using the signal processor, a multidimensional correlation spectroscopic image that includes a multidimensional correlation spectrum at each of the multiple voxels.

Also disclosed is a method for identifying microstructures using magnetic resonance imaging (MRI). The method includes acquiring, using a MRI scanner, acquired data that includes multidimensional information about at least one of diffusion characteristics or relaxation characteristics for each of multiple locations along a spatial plane or in a spatial volume. The method also includes estimating, by a signal processor, a multidimensional correlation spectroscopic image that includes the at least one of the diffusion characteristics or the relaxation characteristics at each of the multiple locations. The method also includes outputting, by an output device, the multidimensional correlation spectroscopic image that includes a multidimensional correlation spectrum at each of the multiple locations.

Also disclosed is a system for identifying microstructures using magnetic resonance imaging (MRI). The system includes a MRI scanner configured to perform MRI scans. The system also includes a MRI controller coupled to the MRI scanner and configured to control the MRI scanner to acquire a dataset that includes data by simultaneously varying at least two encoding parameters at multiple locations, the at least two encoding parameters including at least one of a relaxation contrast encoding parameter or a diffusion contrast encoding parameter. The system also includes a signal processor coupled to the MRI scanner and configured to create a model of the dataset and to estimate a multidimensional correlation spectroscopic image that includes a multidimensional correlation spectrum for each of the multiple locations.

### BRIEF DESCRIPTION OF THE DRAWINGS

Other systems methods, features, and advantages of the present invention will be or will become apparent to one of ordinary skill in the art upon examination of the following figures and detailed description.

FIG. 1 is a block diagram illustrating a system for identifying microstructures and tissue using magnetic resonance imaging (MRI) according to an embodiment of the present disclosure;

FIG. 2 is a flowchart illustrating a method for identifying microstructures and tissue using MRI according to an embodiment of the present disclosure;

FIG. 3 illustrates plots of a numerical simulation setup and estimation results for three different multi-compartment datasets with different diffusion-relaxation correlation characteristics using the method of FIG. 2 according to an embodiment of the present disclosure;

FIG. 4 illustrates structural components used to assemble a custom-built diffusion-relaxation phantom, and example data and estimation results using the phantom and the method of FIG. 2 according to an embodiment of the present disclosure;

FIG. 5 is a table illustrating desired D and T₂ values and corresponding concentrations of materials used in the phantom of FIG. 4 according to an embodiment of the present disclosure;

FIG. 6 illustrates estimation results using conventional 1D diffusion MRI, conventional 1D relaxation MRI, and voxel-by-voxel MRI using the method of FIG. 2 without spatial regularization according to an embodiment of the present disclosure;

FIG. 7 illustrates a set of twenty-eight (28) diffusion and relaxation encoded images from a single slice of a representative control mouse spinal cord using the method of FIG. 2 according to an embodiment of the present disclosure;

FIG. 8 illustrates reference images and spatially-averaged spectra from control spinal cords and injured spinal cords of mice using the method of FIG. 2 and corresponding to a parallel diffusion encoding orientation according to an embodiment of the present disclosure;

FIG. 9 illustrates spatially-varying spectra using the method of FIG. 2 from a boundary between white matter and gray matter in a control spinal cord according to an embodiment of the present disclosure;

FIG. 10 illustrates representative spatially-averaged spectra estimated using the method of FIG. 2 and corresponding to a perpendicular diffusion encoding orientation according to an embodiment of the present disclosure;

FIG. 11 illustrates spatial maps of integrated spectral peaks estimated using the method of FIG. 2 and data acquired using a parallel diffusion orientation according to an embodiment of the present disclosure;

FIG. 12 illustrates estimation results using conventional 1D diffusion MRI, conventional 1D relaxation MRI, and voxel-by-voxel spectra estimated using the method of FIG. 2 without spatial regularization according to an embodiment of the present disclosure;

FIG. 13 illustrates spatial maps of integrated peaks estimated using the method of FIG. 2 with data acquired using a perpendicular diffusion orientation according to an embodiment of the present disclosure; and

FIG. 14 illustrates a reference image and estimation results from an in vivo human brain using the method of FIG. 2 and corresponding to two dimensional T₁ relaxation and T₂ relaxation encoding according to an embodiment of the present disclosure.

### DETAILED DESCRIPTION

Multi-exponential modeling of magnetic resonance (MR) diffusion or relaxation data is commonly used to infer different microscopic tissue compartments that contribute signals to macroscopic MR imaging voxels. However, multi-exponential estimation is known to be difficult and ill-posed. Observing that this ill-posedness is theoretically reduced in higher dimensions, the present disclosure describes a novel multidimensional imaging system and method that jointly encodes multidimensional diffusion and/or relaxation information, and then uses a novel constrained reconstruction technique to generate a multidimensional correlation spectrum for every voxel. The method is referred to as Diffusion-Relaxation Correlation Spectroscopic Imaging (DR-CSI). The peaks of the multidimensional spectrum correspond to distinct tissue microenvironments that are present within each macroscopic imaging voxel.

The capabilities of DR-CSI have been demonstrated using numerically simulated datasets and several experimental datasets. DR-CSI provides substantially greater multi-compartment resolving power relative to conventional diffusion and relaxation based methods.

The DR-CSI approach provides powerful new capabilities for resolving different components of multi-compartment tissue models, and can be leveraged to significantly expand the insights provided by MRI in studies of tissue microstructure.

It is well known that many important biological changes to living tissues (due to development, aging, injury, disease, scientific intervention, etc.) initially occur at microscopic spatial scales. However, due to the limited sensitivity of magnetic resonance imaging (MRI), it is relatively difficult to generate high-resolution MR images in a reasonable amount of time, meaning that conventional MR data is acquired using relatively large imaging voxels that are too large to directly interrogate microscopic tissue features.

Despite the apparent resolution barrier, the scientific community has still invested decades of effort attempting to infer microscopic-scale tissue information from MRI data. Since the direct approach is generally impractical, existing MRI-based methods have focused on indirect approaches that leverage the fact that certain MRI contrast mechanisms are sensitive to microscopic structure. For example, diffusion MRI leverages the fact that the MR signal can be sensitized to the random microscopic diffusion of water molecules through tissue, while relaxation MRI leverages the fact that the relaxation characteristics of the MR signal are sensitive to the local physical and chemical microenvironment. While there has been considerable progress in using diffusion and relaxation information to infer microstructure, existing methods still suffer from ambiguities, and there remains a pressing need for new MRI methods that can estimate microstructural tissue compartments with higher sensitivity and specificity.

Existing microstructure estimation methods make the observation that, assuming negligible intercompartmental exchange, the signal observed from a macroscopic voxel can be viewed as a simple summation of the signals that would have been observed from each of the distinct tissue “compartments” (i.e., ensembles of nuclei that share the same local tissue microenvironment) that are present within the voxel. This observation has led to a variety of multi-compartment modeling schemes that have been proposed for inferring the contributions of different microstructural compartments to the relaxation or diffusion signal decay curves. For example, multi-compartment T₂ or T₂*estimation can be used to infer the relative contributions of the myelin water, intracellular water, and extra-cellular water compartments to the signal observed from a single voxel of brain white matter, assuming that each of these tissue compartments is associated with distinct relaxation characteristics. As another example, multi-compartment modeling of the diffusion decay curve has been used to distinguish hindered and restricted water diffusion compartments within a single voxel in a variety of settings.

However, it is important to note that the interpretation of existing multi-compartment modeling results is not always straightforward, especially in cases where the multi-compartment estimation problem is ill-posed. As a prototypical example of this, bi-exponential and multi-exponential estimation problems are frequently encountered in both relaxation-based and diffusion-based multi-compartment modeling. These estimation problems have been widely studied, and a substantial amount of theoretical analysis and empirical evidence has shown that they are often ill-posed. For example, it was suggested more than 200 years ago that there may be a fundamental limit in the ability to separate two superposed exponentials with similar decay constants. More recent analysis has shown that different multi-exponential models can be “numerically equivalent” with respect to the decay curve they produce, despite having substantial differences in the model parameters.

The ill-posedness of multi-exponential estimation has led certain members of the scientific community to be very pessimistic about this type of estimation problem—an often-quoted statement is that anyone attempting multi-exponential fitting should be “spanked or counseled.” While not everyone shares this extreme point of view, and multi-exponential modeling has been successful in a variety of MRI application contexts, it is undeniable that it is relatively difficult to use relaxation data alone to separate tissue compartments that have similar relaxation constants, and it is similarly difficult to use diffusion data alone to separate tissue compartments that have similar diffusion coefficients. In both cases, there are theoretical resolution limits to how well diffusion spectra and relaxation spectra can be estimated, and these limits cannot be overcome through incremental adjustments to conventional diffusion or relaxation experiments.

This disclosure describes a novel approach to estimating multi-compartment tissue models, DR-CSI, which is designed to mitigate the “spectral resolution” problems associated with conventional relaxation-based and diffusion-based multi-compartment modeling approaches. The approach to DR-CSI described herein is motivated by two distinct observations, which each independently suggest that the fundamental resolution limitations of previous methods can be overcome by addressing the multi-compartment estimation using higher-dimensional contrast encoding and parameter estimation approaches.

The first observation is that the previously-described theoretical ill-posedness of multi-exponential estimation was derived assuming that model fitting would be performed independently for each voxel. However, an imaging experiment would yield multiple voxels, and if the spatial resolution is high enough, the multi-exponential decay structure from one voxel would generally be expected to have some degree of correlation with the multi-exponential structure from its spatial neighbors. Recent estimation-theoretic analysis has shown that this spatial correlation structure can dramatically reduce the ill-posedness of the multi-exponential estimation process. This suggests a higher-dimensional version of the estimation problem in which the parameters for all voxels are estimated jointly, rather than using the standard voxel-by-voxel estimation approach. This theoretical result is also supported by recent empirical observations that solve multi-exponential estimation problems using spatial regularization.

The second observation is that while diffusion encoding alone or relaxation encoding alone may suffer from ambiguities whenever two tissue compartments have similar decay parameters, it is often possible to resolve these ambiguities by using higher-dimensional contrast encoding schemes that simultaneously and non-separably encode multidimensional diffusion and/or relaxation characteristics. Based on this kind of data, the DR-CSI method estimates a multidimensional diffusion-relaxation correlation spectrum for each voxel.

To take full advantage of these two observations, the new DR-CSI method combines multidimensional contrast encoding with spatial encoding and multidimensional spatially-regularized spectrum estimation techniques. The evaluation of DR-CSI using numerical simulations and data from real MRI experiments demonstrates the powerful capabilities of this new approach.

There are multiple ways that multidimensional DR-CSI could potentially be implemented, because there are multiple diffusion and relaxation characteristics that may be of interest. On the relaxation side, there are several different relaxation parameters to choose from (e.g., T₁,T₂,T₂*, etc.) which will each have more or less sensitivity to different parameters of the acquisition pulse sequence (e.g., the repetition time TR, the echo time TE, the flip angle α, etc). On the diffusion side, there are also several different diffusion decay models to choose from (e.g, isotropic versus anisotropic diffusion, Gaussian versus non-Gaussian diffusion within each compartment, etc.) that will also have more or less sensitivity to various parameters of the acquisition pulse sequence (i.e., the diffusion encoding b-value, the diffusion time Δ, the diffusion encoding orientation, etc.). For the sake of simplicity and concreteness and without loss of generality, the present disclosure describes DR-CSI assuming an interest in estimating simple two-dimensional (2D) diffusion-relaxation correlation spectra, combining a simple one-dimensional (1D) exponential diffusion decay model characterized by the apparent diffusion coefficient D with a 1D exponential relaxation decay model characterized by the transverse relaxation constant T₂.

To aid the description of DR-CSI, the models used in standard T₂ relaxometry and diffusometry will be described. In T₂ relaxometry, the ideal (noiseless) signal model for a single voxel containing a single tissue compartment with mono-exponential relaxation will obey Equation 1 below:

m(TE)=fe^{-TE/T}^{₂} Equation 1:

In Equation 1, the signal is parameterized by its unknown amplitude ƒ and its decay parameter T₂. The corresponding multi-compartment model is generally either described using a discrete model with N_{c} distinct components as shown in Equation 2 below:

m(TE)=Σₙ₌₁^{N}^{_{c}}ƒₙe^{-TE/T}^{ₙ}^{ⁿ} Equation 2:

Or as a continuum model as shown in Equation 3 below:

m(TE)=∫ƒ(T₂)e^{-TE/T}^{₂}dT₂ Equation 3:

The discrete model is often used when the number of components N can be estimated a priori, while the continuum model is more general (and includes the discrete model as a special case). Due to its generality and to be consistent with the previous correlation spectroscopy literature, this disclosure focuses on continuum models. This disclosure will refer to the distribution function ƒ(T₂) appearing in the continuum model as the 1D relaxation spectrum, and its value is proportional to the signal contribution from spins that experience relaxation governed by the associated T₂ parameter.

The model for 1D diffusion decays is similar, with the ideal signal for the multi-compartment continuum model shown in Equation 4 below:

m(b)=∫ƒ(D)e^{-bD}dD Equation 4:

The present disclosure will refer to the distribution function ƒ(D) as the 1D diffusion spectrum.

Higher-dimensional approaches like DR-CSI are natural generalizations of these 1D approaches, and for a single-voxel, will use ideal multidimensional signal models illustrated in Equation 5 below:

m(b,TE)=∫∫ƒ(D,T₂)e^{-bD}e^{-TE/T}^{₂}dDdT₂ Equation 5:

In Equation 5, ƒ(D, T₂) is a 2D distribution function that will be referred to as a 2D diffusion-relaxation correlation spectrum. The 2D spectrum has more information than either of the 1D spectra ƒ(D) or ƒ(T₂), which can each be thought of as lossy 1D projections of ƒ(D, T₂). For example, if two tissue compartments have similar D values but different T₂ values, then they would be hard to resolve from ƒ(D), but much easier to resolve from ƒ(D, T₂). Similarly, two tissue compartments with similar T₂ values may be much easier to resolve from ƒ(D, T₂) than they would have been from ƒ(T₂). On the other hand, estimation of ƒ(D, T₂) requires a different experiment design compared to estimation of ƒ(D) or ƒ(T₂). While 1D contrast encoding (varying either b or TE) is necessary to estimate 1D spectra, methods like DR-CSI require 2D contrast encoding, with images sampled at multiple b,TE combinations.

DR-CSI uses a relatively high-dimensional model. Assuming 2D imaging (without loss of generality) with spatial coordinates (x,y), then the ideal signal model used by DR-CSI is shown in Equation 6 below:

m(x,y,b,TE)=∫∫ƒ(x,y,D,T₂)e^{-bD}e^{-TE/T}^{₂}dDdT₂ Equation 6:

In Equation 6, ƒ(x, y, D, T₂) is a 4D function, including a full 2D diffusion-relaxation correlation spectrum at every voxel (i.e., at each (x,y) location), which is referred to as a 4D spectroscopic image.

Spectrum estimation involves deriving ƒ(D), ƒ(T₂), ƒ(D, T₂), or ƒ(x, y, D, T₂) spectra from sampled noisy measurements of m(b), m(T₂), m(b,TE), or m(x, y, b,TE). Due to space constraints, the present disclosure uses notation that corresponds to the 4D DR-CSI formulation, though unless otherwise noted, the estimation procedures used by existing 1D and 2D spectroscopic methods are similar.

Existing methodologies use a dictionary-based approach for spectrum estimation, and the present disclosure uses a similar approach for DR-CSI. The dictionary-based approach replaces the continuum integral from Equation 6 with standard Riemann sums shown in Equation 7 below:

$$m ( {x}_{i} , {y}_{i} , {b}_{p} , {TE}_{p} ) = {\sum }_{q = 1}^{Q} {w}_{q} f ( {x}_{i} , {y}_{i} , {D}_{q} , {T}_{2}^{q} ) {e}^{- {b}_{p} {D}_{q}} {e}^{- \frac{{TE}_{p}}{{T}_{2}^{q}}} \qquad Equation 7$$

for i=1, . . . N and p=1, . . . P, which can be equivalently written in matrix-vector form as shown in Equation 8 below:

mᵢ=Kfᵢ Equation 8:

for i=1, . . . N. In Equations 7 and 8, it is assumed that there are N different voxel locations (xᵢ,yᵢ), =1, . . . N; the data is collected with P different combinations of diffusion and relaxation encoding bₚ,TEₚ,p=1, . . . P; the continuum distribution has been sampled at a large number Q of preselected D_{q},T₂^{q} values, q=1, . . . Q; and w_{q} is the density normalization term associated with the Riemann sum. The Riemann sum approximation of the continuum integral is well known to have arbitrarily good accuracy as Q is allowed to be larger. In the matrix-vector expression, the vector mᵢ∈R^{P} is the set of all observed data samples from the i^{th} voxel, the matrix K∈R^{P×Q} has entries

$${[ K ]}_{pq} = {w}_{q} {e}^{- {b}_{p} {D}_{q}} {e}^{- \frac{TEp}{{T}_{2}^{q}}} ,$$

and the vector fᵢ∈R^{Q} is the vectorized 2D diffusion-relaxation correlation spectrum ƒ(xᵢ,yᵢ,D_{q},T₂^{q}) from the i^{th} voxel.

Notably, the K matrix is often poorly-conditioned due to the strong similarity between exponential decays with similar decay constants, and it is standard to use additional constraints for spectrum estimation in 1D and 2D approaches. A nearly universal approach for estimating relaxation, diffusion, or diffusion-relaxation correlation spectra is to define mᵢ using the magnitude of the observed signal (discarding the phase), and assuming the spectra fᵢ are real and nonnegative. This same nonnegativity constraint is used in DR-CSI. DR-CSI also uses a spatial smoothness constraint, which is reasonable because tissue characteristics often vary smoothly in space, and spatially-neighboring voxels would generally be expected to have similar 2D correlation spectra. This spatial smoothness constraint is only possible in the context of an imaging experiment like DR-CSI, and based on the first observation, is expected to add substantially to the estimation performance. Combining all of these constraints, the multidimensional spectral estimation problem is formulated as the solution to the following optimization problem of Equation 9:

$${\{ {\hat{f}}_{i} \}}_{i = 1}^{N} = {arg min}_{{\{ {f}_{i} \}}_{i = 1}^{N}} {\sum }_{i = 1}^{N} [ {t}_{i} \vert \vert {m}_{i} - {Kf}_{i} {\vert \vert}_{2}^{2} + {𝕀}_{+} ( {f}_{i} ) + {\sum }_{j ∈ Δ i} \vert \vert {f}_{j} - {f}_{i} {\vert \vert}_{2}^{2} ] \qquad Equation 9$$

In Equation 9, {fᵢ}ᵢ₌₁^{N} [symbol] {f₁, f₂, . . . f_{N}} is the set of spectra from every voxel, and Ai is the index set for the voxels that are directly adjacent to the i^{th} voxel. Equation 9 has three terms, which respectively correspond to a data consistency constraint, a nonnegativity constraint, and a spatial regularization constraint.

The data consistency constraint is used to enforce the fact that the estimated spectra should match the measured data reasonably well. Data consistency is measured using the l₂-norm to simplify the optimization algorithm, and while the l₂-norm implicitly assumes that the noise distribution is Gaussian (which, for magnitude images, is approximately valid at high signal to noise ratios (SNR)), it would be straightforward to more accurately model the Rician or non-central chi signal distributions associated with low-SNR magnitude images using the l₂-norm optimization strategy. The data consistency constraint also uses scalars tᵢ to avoid fitting multidimensional correlation spectra to noise-only voxels of the image. Specifically, tᵢ=0 is taken if the i^{th} voxel is outside the object, and otherwise tᵢ=1 is taken. Since spatial regularization constraints are used, this masking of noise-only voxels helps prevent noise-only spectra from contaminating the spectra of interest.

The function used to impose nonnegativity constraints, [symbol] ₊+(fᵢ), is defined as [symbol] ₊(fᵢ)=∞ if any element of (fᵢ) is negative, and [symbol] ₊(fᵢ)=0 otherwise.

The spatial regularization term is a standard finite-difference approximation to the continuum penalty function and can be shown by Equation 10 below:

$$λ \int \int \int \int \{ \vert \frac{\partial }{\partial x} f ( x , y , D , {T}_{2} ) {\vert}^{2} + \vert \frac{\partial }{\partial y} f ( x , y , D , {T}_{2} ) {\vert}^{2} \} {dxdydDdT}_{2} \qquad Equation 10$$

which encourages spatial smoothness by penalizing the spatial derivatives of the 4D spectroscopic images. The regularization parameter A is used to adjust how strongly the spatial smoothness constraints are enforced.

The optimization problem in Equation 9 is convex, and can be globally optimized from any initialization using standard convex optimization methods. A popular approach that is based on variable splitting and the alternating direction method of multipliers (ADMM) may be used to solve this problem.

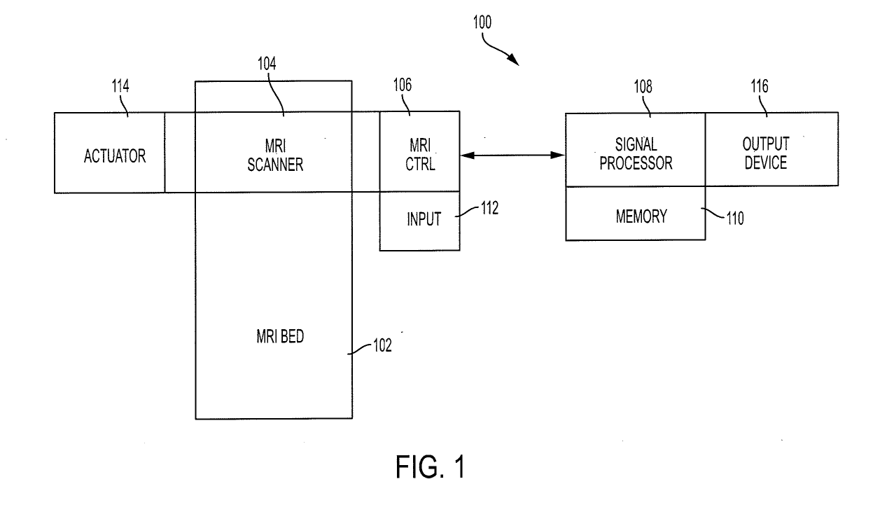

FIG. 1 illustrates a system 100 for identifying microstructures and tissue using magnetic resonance imaging (MRI). The system 100 may be used to implement the DR-CSI method described above and below.

The system 100 includes a platform 102, such as a MRI bed, where a target to be scanned may be located. Where used throughout the disclosure, “target” refers to any object, person, animal, or other subject of a MRI scan. The system 100 further includes a MRI scanner 104 that is designed to perform MRI scans. The system 100 further includes a MRI controller 106 designed to control the MRI scanner 104. The system 100 further includes a signal processor 108 in digital communication with the MRI controller 106, and a non-transitory memory 110 coupled to the signal processor 108. The system 100 further includes an actuator 114 coupled to the MRI scanner 104 and configured to actuate the MRI scanner 104. The system 100 may further include an input device 112 which may include any input device such as a mouse, a keyboard, a touchscreen, or the like. The system 100 may further include an output device 116 which may include any output device such as a display, a speaker, a touchscreen, or the like.

The MRI scanner 104 may use one or more of magnetic fields to generate images that correspond to tissue, such as organs in a body. The MRI scanner 104 may be capable of generating MRI images that include high dimensional data including at least two spatial dimensions and at least two contrast encoding dimensions. For example, the at least two contrast encoding dimensions may include a relaxation encoding dimension and a diffusion encoding dimension, two relaxation encoding dimensions, or the like.

The MRI controller 106 may include any controller or processor capable of transmitting and/or receiving radio frequency signals. For example, the MRI controller 106 may include a general purpose processor, a digital signal processor (DSP), an application specific integrated circuit (ASIC), a field programmable gate array (FPGA) or other programmable logic device, discrete gate or transistor logic, discrete hardware components, or any combination thereof capable of controlling the MRI scanner 104.

In some embodiments, the MRI scanner 104 may include the actuator 114 that actuates the MRI scanner 104 relative to a target located on the platform 102. In that regard, the MRI controller 106 may control the actuator 114 of the MRI scanner 104 to cause the MRI scanner 104 to scan desired locations of the target.

In some embodiments, the input device 112 may be used to provide control instructions to the MRI controller 106. For example, the control instructions may include desired spatial control of the MRI scanner 104 (i.e., may correspond to control of the actuator 114), may include desirable parameters of the encoding dimensions, or the like.

The MRI controller 106 may further control the MRI scanner 104 to acquire MRI data (such as images) that include multiple dimensions. The dimensions may include at least two spatial dimensions and at least two contrast encoding dimensions. For example, the MRI controller 106 may control the MRI scanner 104 to acquire two-dimensional spatial images that encode information about diffusion characteristics and/or relaxation characteristics at each of multiple locations along the at least two spatial dimensions.

The signal processor 108 may include a general purpose processor, a digital signal processor (DSP), an application specific integrated circuit (ASIC), a field programmable gate array (FPGA) or other programmable logic device, discrete gate or transistor logic, discrete hardware components, or any combination thereof. The signal processor 108 may receive the data acquired by the MRI scanner 104 and may estimate a multidimensional correlation spectroscopic image based on the received data, including a multidimensional correlation spectrum for each spatial location (i.e., for each voxel). The multiple dimensions may include, for example, at least two spatial dimensions and at least two spectral dimensions. For example, the at least two spectral dimensions may include diffusion characteristics and/or relaxation characteristics.

The signal processor 108 may also construct spatial maps of peaks in the higher dimensional spectrum based on the spectroscopic image. The signal processor 108 may also control the output device 116 to output data such as the multidimensional correlation spectra from each voxel, the spectroscopic image, the spatial maps of the peaks, or the like.

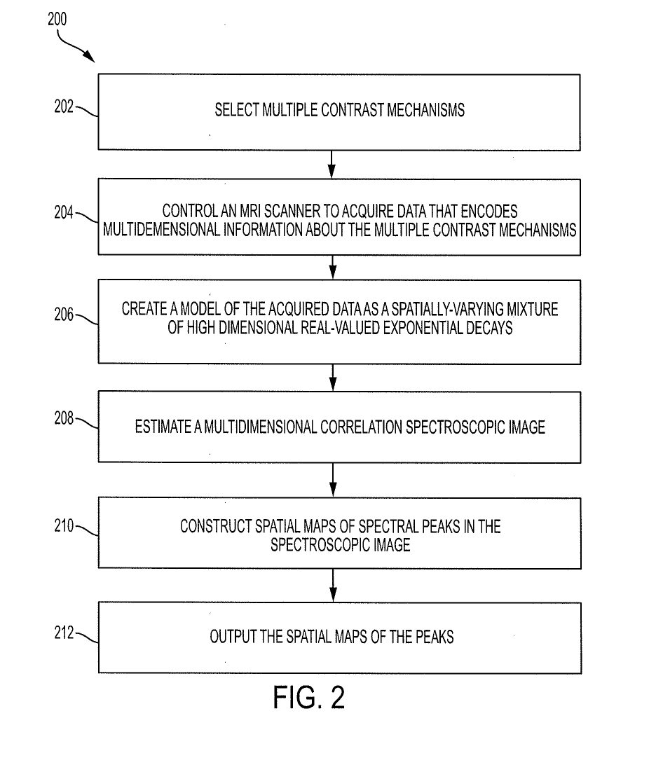

Turning now to FIG. 2, a method 200 for performing DR-CSI is shown. The method 200 may be used for identifying and spatially mapping microenvironments using coarse resolution correlation spectroscopic imaging.

In block 202, multiple contrast mechanisms may be selected. For example, the multiple contrast mechanisms may be selected by a user using an input device that is coupled to an MRI controller. The contrast mechanisms may include relaxation contrast mechanisms (such as T₁ and T₂ relaxation parameters), diffusion contrast mechanisms (such as apparent diffusion coefficients), or the like.

In block 204, an MRI controller may control an MRI scanner to acquire data (such as images) that encodes information about the multiple contrast mechanisms. For example, the data may include four or more dimensions. At least two of the dimensions may be spatial dimensions (such as along an X-Y plane) and at least two of the dimensions may correspond to contrast encoding dimensions (such as diffusion weighting values to encode diffusion coefficients, and echo times to encode T₂ relaxation parameters). In that regard, the data may include multiple diffusion encodings and multiple relaxation encodings at each spatial location (each voxel, or each (x,y) location along the X-Y plane).

In block 206, the signal processor 108 may receive the acquired data and may create a model of the acquired data. For example, the model may be created using an equation similar to Equation 6 above, or a discretized approximation thereof.

In Equation 6, m(x,y,b,TE) is the high-dimensional contrast encoded data at a spatial location x, y, at a diffusion encoding value b, and at an echo time TE, and ƒ(x, y, D, T₂) is a 4D spectroscopic image as a function of a diffusion coefficient D and a relaxation parameter T₂.

In block 208, a multidimensional correlation spectroscopic image may be estimated, including a multidimensional correlation spectrum at each voxel (i.e., at each spatial location x, y). The multidimensional correlation spectroscopic image may be estimated using an equation that includes a data consistency constraint, a non-negativity constraint, and a spatial regularization constraint. For example, and as discussed above, the multidimensional correlation spectrum may be estimated using an equation similar to Equation 9.

In Equation 9, {\hat{f}}ᵢ₌₁^{N} represents the estimated multidimensional correlation spectroscopic image, i represents each voxel (each combination of an x location and a y location), mᵢ represents the acquired data at an i^{th} voxel, K is a matrix representing a decaying signal, fᵢ represents the estimated multidimensional correlation spectrum at each voxel, and tᵢ represents constants to avoid fitting the multidimensional correlation spectra to noise-only voxels of the image.

In block 210, the signal processor 108 may construct spatial maps of spectral peaks in the spectroscopic image. The peaks may correspond to microstructure in the tissue of the target, and may signal damage or other abnormality in the tissue.

In block 212, the signal processor may control an output device to output data, such as the estimated multidimensional correlation spectra for different voxels, the spectroscopic image, the spatial maps of the peaks, or the like.

Simulations were performed using the method 200 and a system similar to the system 100 of FIG. 1. In particular, three different numerical datasets were constructed, with each simulation corresponding to estimation of a 3-compartment model.

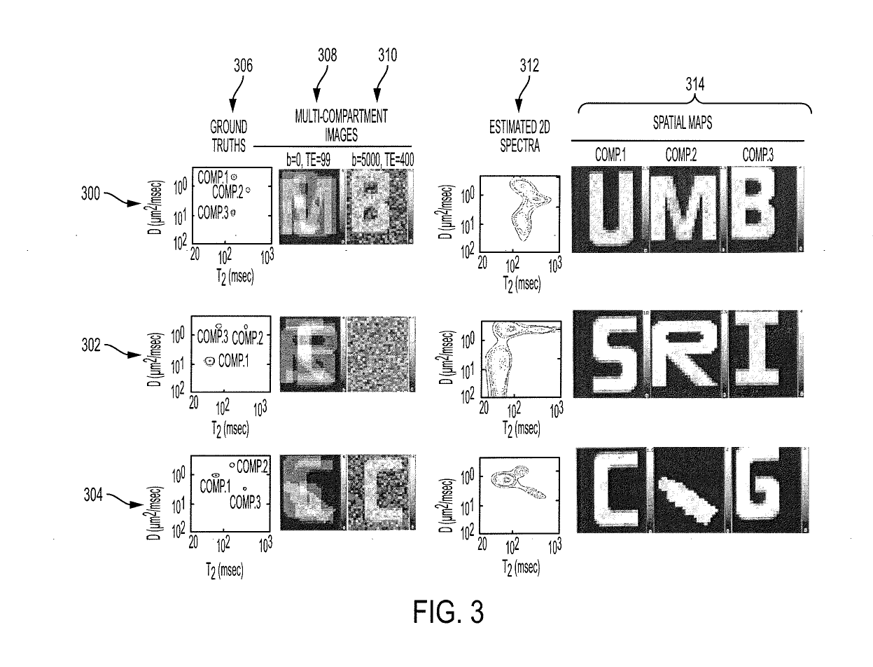

Referring to FIG. 3, the three leftmost columns 306, 308, 310 illustrate setups of simulations, with each simulation shown in a corresponding row 300, 302, 304. A first column 306 illustrates ground truth 2D diffusion-relaxation correlation spectrum (averaged across all voxels). A second column 308 and a third column 310 illustrate representative simulated diffusion and relaxation encoded images (in the second column 308, b=0 s/mm² and TE=99 ms; and in the second column 310, b=5000 s/mm² and TE=400 ms), respectively. The simulated diffusion and relaxation encoded images illustrate the geometry of compartmental overlap and noise levels. A fourth column 312 illustrates 2D spectra estimated using the method 200 of FIG. 2 (i.e., DR-CSI) averaged across all voxels of the spectroscopic image. The last three columns 314 illustrate spatial maps of the integrated spectral peaks from the estimated spectroscopic images.

In each simulation, the compartments were each given a different ideal single-peak D−T₂ spectrum f_{c}(D,T₂) with a logarithmic 2D Gaussian lineshape, and a distinct binary spatial mask for each compartment a_{c}(x,y). The ideal three compartment model was generated using a simple summation shown in Equation 11 below:

ƒ(x,y,D,T₂)=Σ_{c=1}³a_{c}(x,y)ƒ_{c}(D,T₂) Equation 11:

Noiseless DR-CSI measurements were simulated from this ideal model according to Equation 6, and data was sampled at every combination of 7 b-values (0, 200, 500, 1000, 1500, 2500 and 5000 s/mm²) and 7 TE values (99, 120, 150, 190, 240, 300 and 400 ms), for a total of P=49 images. Gaussian noise was subsequently added to these images. Finally, the image phase was discarded, resulting in magnitude images following a Rician distribution. The highest-SNR image (i.e., the least amount of diffusion and relaxation decay, with b=0 s/mm² and TE=99 ms) had a SNR of 20, with SNR defined as the ratio between the average signal intensity and the noise standard deviation.

For each multi-compartment simulation, spectroscopic images were estimated using the following parameters: the dictionary K was constructed using every combination of 80 D values (logarithmically distributed from 0.001 to 5 μm²/ms) and 80 T₂ values (logarithmically distributed from 20 to 1000 ms) for a total of Q=80×80 dictionary elements. DR-CSI estimation was performed using λ=0.1, μ=0.1, and zero initialization.

DR-CSI was used to estimate a 4D spectroscopic image including a 2D spectrum for every voxel in the image, and the average spectra (integrated across all voxels) are shown in the column 312 for each simulation. In each case, the average spectra have three distinct peaks that are largely consistent with the peaks from the ground truth spectra shown in the first column 306 of FIG. 3. Compared to the ground truth, the estimated peaks have broader lineshapes. This lineshape broadening is expected to be a consequence of the finite spectral resolution associated with finite data sampling and noise.

The last 3 columns 314 illustrate the spatial variations of each spectral peak appearing in the spatially-averaged spectrum. Specifically, each image shows a spatial map of an integrated spectral peak. Despite the relatively high noise level in some of the simulated images, the three different original compartments are successfully separated in all three simulations.

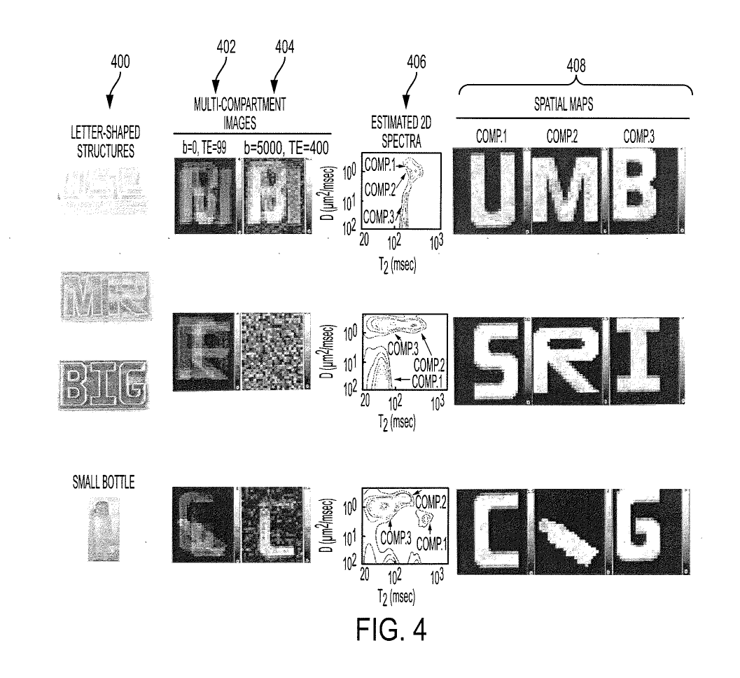

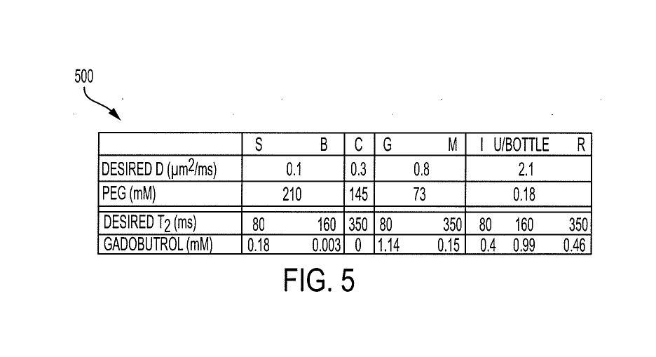

For comparison against the numerical simulation results, phantom structures were created. Referring to FIG. 4, a column 400 illustrates the shape of the phantom structures. The letter-shaped structures were formed using 3D printing, and liquid rubber was used for waterproofing. Each compartment of the phantom was filled with a different mixture of Polyethylene Glycol (PEG) (available under the brand name Up&up™ powderlax; from Target Corporation of Minneapolis, Minn., at 3350 g/mol) and gadobutrol (available under the brand name gadovist; from Bayer Healthcare of Leverkusen, Germany, at 1 mmol/ml) to respectively adjust the D and T₂ values. The specifications of each solution are given in a table 500 of FIG. 5.

DR-CSI datasets were acquired using a 3 Tesla (3T) human system (available under the brand name Achieva; from Philips Healthcare, Best, The Netherlands) using a diffusion-weighted spin-echo imaging sequence and an 8-channel head coil with the following parameters: repetition time (TR)=11000 ms, voxel size=3 mm×3 mm, matrix size=64×40, slice thickness=5 mm, and 33 slices. Contrast encoding used the same set of (b,TE) parameters that were used in the numerical simulations (P=49).

The data was acquired with thin slices so that there was no overlap between compartments within a single slice. Three different 3-compartment datasets were generated by overlaying and summing single-compartment data from different slices. Representative 3-compartment images are shown in columns 402, 404 of FIG. 4 (b, c, d). DR-CSI estimation was performed using the same parameters as used in the numerical simulations.

DR-CSI was compared against voxel-by-voxel DR-CSI (performed without spatial regularization), conventional 1D relaxation, and conventional 1D diffusion methods. Voxel-by-voxel DR-CSI solves a similar estimation problem to the one used in Diffusion-Relaxation Correlation Spectroscopy (DR-COSY), and was implemented using the same problem formulation as Equation 9 without use of spatial regularization λ=0. For the conventional 1D methods, relaxation spectra were estimated from the 7 different TEs acquired with no diffusion weighting, and diffusion spectra were estimated from the 7 different b-values acquired at the shortest echo time. The 1D relaxation and 1D diffusion spectra were both estimated using Equation 9, with the dictionary matrix K modified to include only relaxation or diffusion decays, respectively. For enhanced performance, the 1D spectra were both estimated using spatial regularization. The estimated 2D spectra is shown in a column 406, and the spatial maps of the integrated spectral peaks are illustrated in the last three columns 408.

FIG. 4 (b-d) shows DR-CSI results from the phantom experiment, with the spatially-averaged 2D spectra shown in the column 406 and the spatial maps of integrated spectral peaks shown in the last three columns 408. Accurate separation of the three superposed compartments is also achieved in all three of these cases, and the estimated spectral peak characteristics are largely consistent with the characteristics of the PEG-gadobutrol solutions listed in the table 500 of FIG. 5.

Notably, the spectral characteristics of real data are not as regular as they were in the previous numerical simulation results shown in FIG. 3, and demonstrate irregular lineshapes. This is likely due to a number of practical factors, including truly non-Gaussian spectral lineshapes, spatial variations in the concentrations of the PEG-gadobutrol mixtures, chemical shift artifacts from the PEG spectrum, and external factors like B0 inhomogeneity. Due to the way that the phantom was constructed, field inhomogeneity was observed to be qualitatively much more substantial in this phantom compared to what is observed in typical biological tissues, which may contribute additional spatially-varying diffusion weighting that is not modeled by the estimation scheme. Nevertheless, the DR-CSI method was able to robustly separate distinct spectral peaks which are successfully mapped back to reveal the original compartmental geometry of the phantom.

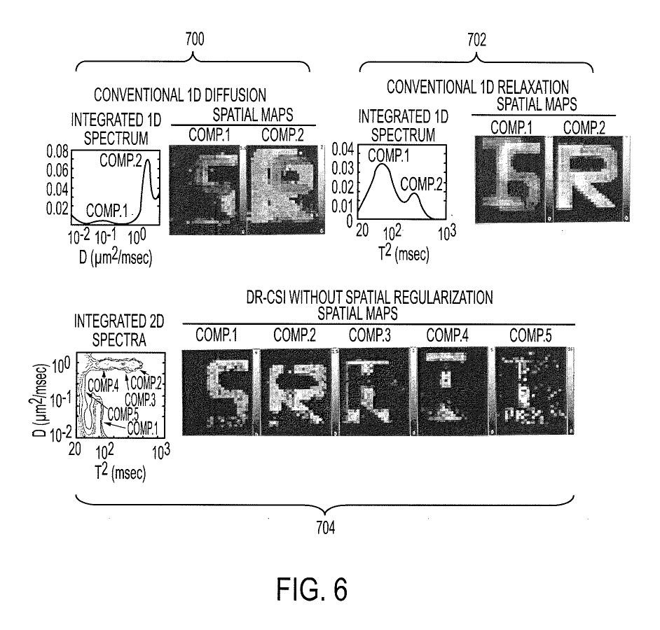

FIG. 6 illustrates results 700 obtained with conventional 1D diffusion, results 702 obtained with conventional 1D relaxation, and results 704 obtained with voxel-by-voxel DR-COSY corresponding to the same multi-compartment data used in FIG. 4. The spatially-integrated spectra for the conventional 1D methods only show two distinct peaks, which is expected based on the diffusion-relaxation characteristics of the compartments. Specifically, as seen in FIGS. 4 and 5, the ‘S’ and ‘I’ compartments have very similar relaxation parameters, while the ‘R’ and ‘I’ compartments have very similar diffusion coefficients. The spatial maps of the integrated peaks demonstrate that, as expected, it is difficult to separate compartments when the decay parameters are too similar to each other. The voxel-by-voxel DR-CSI results are more successful than the 1D approaches, but the spatially-averaged 2D spectrum contains more peaks than the original number of compartments, and the spatial maps of the integrated spectral peaks are not as accurate at reconstructing the true geometries of the original compartments. These results strongly demonstrate that both the multidimensional contrast encoding and multidimensional spectroscopic image estimation components of DR-CSI are important, and that DR-CSI can offer substantially enhanced ability to resolve multiple overlapping compartments compared to the conventional approaches.

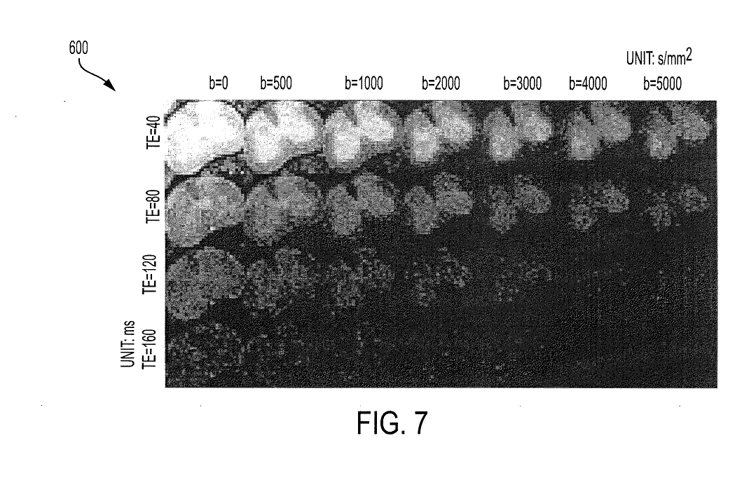

As another experiment, ex vivo mouse spinal cords (three sham controls and three with traumatic spinal cord injury) were scanned using the DR-CSI protocol. Diffusion in the mouse spinal cord is highly oriented, which enables the use of 1D diffusion encoding despite the anisotropic nature of the diffusion process. Two DR-CSI datasets were obtained for each spinal cord, one with diffusion encoding parallel to the axonal tracts and one with diffusion encoding perpendicular to the axonal tracts. Datasets were acquired using a 4.7T animal system (available from Agilent Inc. of Palo Alto, Calif.) using a diffusion-weighted spin-echo imaging sequence with the following parameters: TR=2000 ms, voxel size=0.078 mm×0.078 mm, matrix size=96×96, slice thickness=1 mm, and 5 slices. Data was sampled at every combination of 7 b-values (0, 500, 1000, 2000, 3000, 4000 and 5000 s/mm²) and 4 TE values (40, 80, 120 and 160 ms) for a total of P=28 images. FIG. 7 illustrates a representative full set of 28 DR-CSI contrast encodings 600 from a single slice of a control cord.

For each dataset, 2D spectra were estimated using the following parameters: the dictionary K was constructed using every combination of 70 D values (logarithmically distributed from 0.01 to 5 μm²/ms), and 70 T₂ values (logarithmically distributed from 3 to 300 ms) for a total of Q=70×70=4900 dictionary elements. Similar to the previous section, DR-CSI based results were compared against voxel-by-voxel DR-CSI, conventional 1D relaxation, and conventional 1D diffusion.

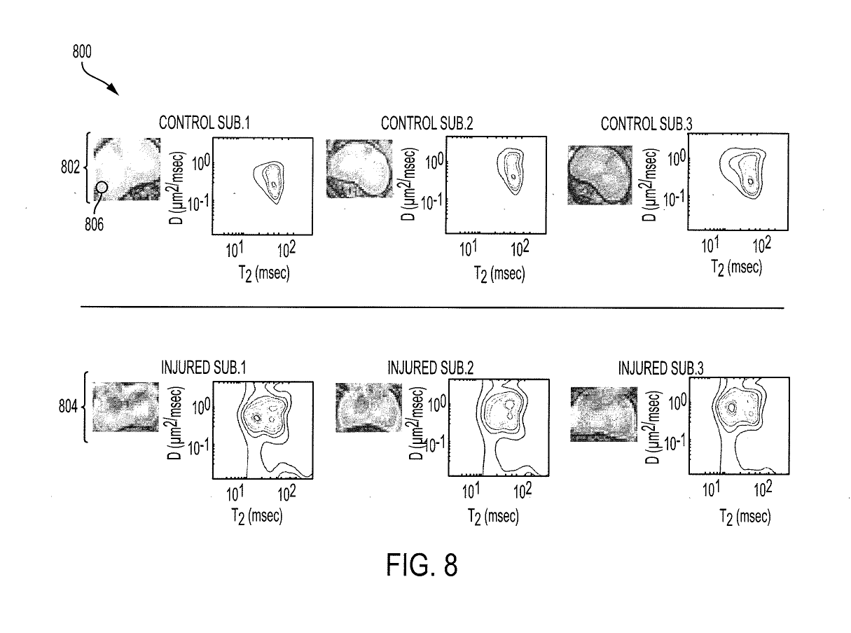

FIG. 8 illustrates DR-CSI results 800 generated from all six of the ex vivo mouse spinal cord datasets acquired with a parallel diffusion encoding orientation. The 2D spectra from the control cords 802 consistently have two distinct well-resolved peaks, as well as a third weaker peak in between. The third peak may not be very visible in the spatially-averaged spectra, although its existence is more clear in many of the 2D spectra obtained from individual voxels. In contrast, the 2D spectra for the injured cords 804 contain an additional peak that was not present in the control spectra.

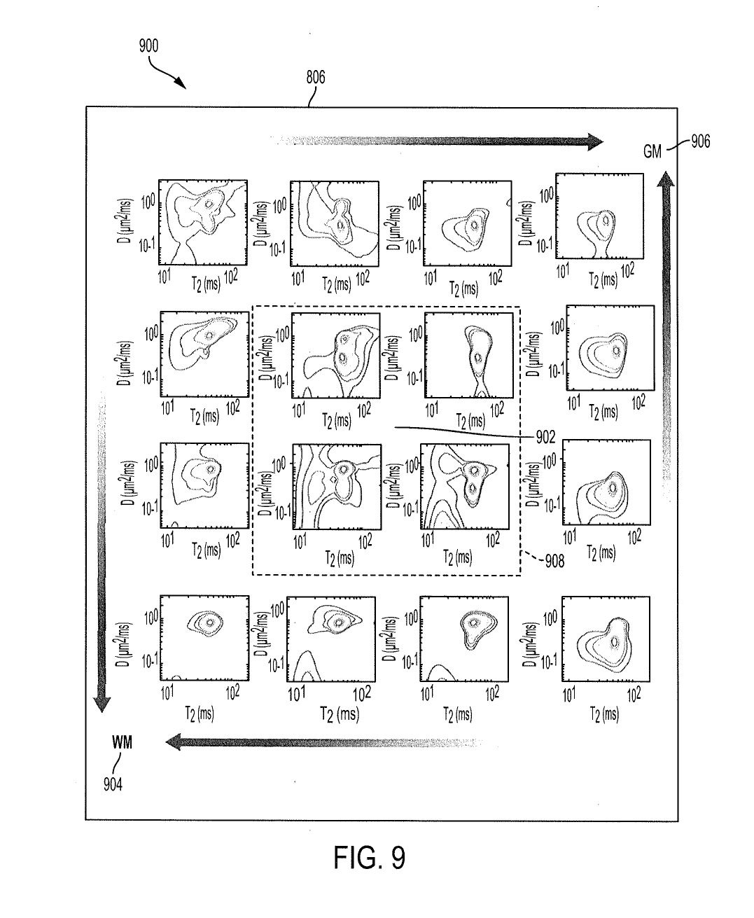

To highlight the spatially-varying nature of the estimated DR-CSI spectroscopic images, FIG. 9 illustrates spatially-varying spectra 900 from a region from the white matter (WM)-gray matter (GM) boundary 902 of the first control cord, from a location 806 of the first control subject 802 of FIG. 8. As can be seen, the spatial distribution of the spectra clearly depicts the transition between white matter 904 and gray matter 906, with one distinct peak in the WM region, a different distinct peak in the GM region, and a combination of the two peaks in the partial volume region 908 at the boundary. Notably, it is not possible to gain this kind of insight from 2D spectroscopy methods like DR-COSY, which do not use spatial encoding.

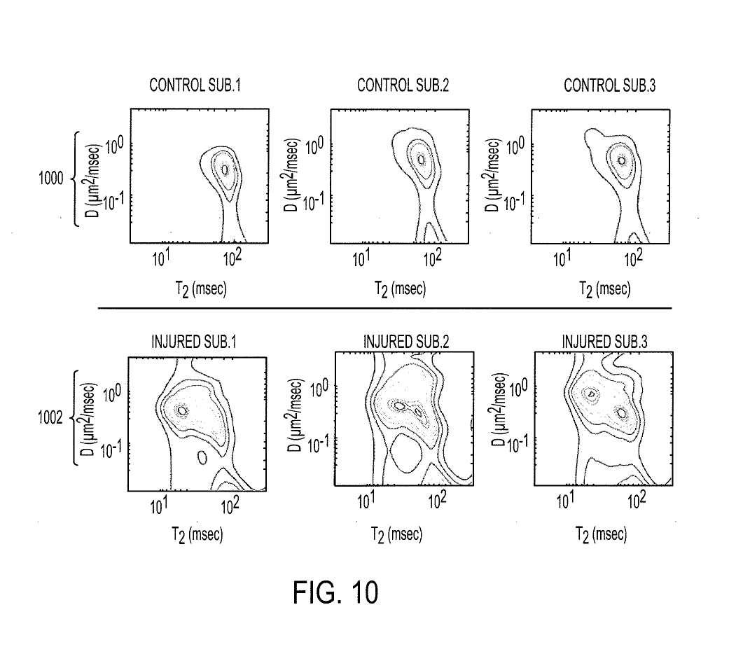

Representative spatially-averaged DR-CSI spectra from a perpendicular diffusion encoding orientation are shown in FIG. 10. The spectral peaks in this case are more closely spaced than they were for the parallel orientation, and, for example, it is more difficult to visually separate multiple peaks from the spatially-averaged 2D spectrum from the control cord. Nevertheless, there is a clear additional peak in the spectrum from the injured cords 1002 that were not present in the spectrum of the control cords 1000.

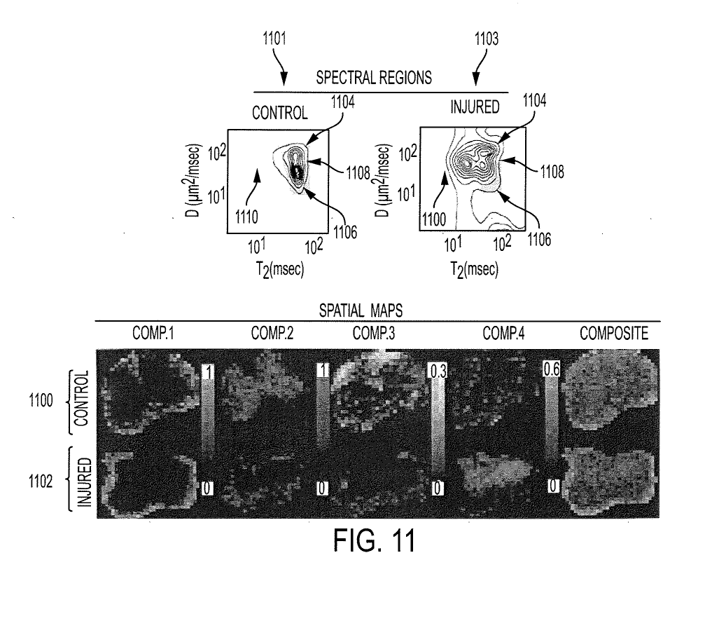

Representative spatial maps generated by integrating spectral regions from the DR-CSI spectroscopic images are shown in FIG. 11. Spectral regions are shown for a control cord 1101 and for an injured cord 1103. There is no ground truth for this case, and each of these estimated components cannot definitively be associated with distinct components of the tissue microstructure without additional investigations that are beyond the scope of this disclosure (e.g., histology). However, as can be seen, spatial maps 1100 for the control cords seem consistent with the known anatomy of the spinal cord. Specifically, in all cases, a first component 1104 appears to correspond to white matter, a second component 1106 appears to correspond to gray matter, and a third component 1108 also appears to correspond to gray matter, but with a larger signal from the dorsal gray matter than from the ventral gray matter (except in cases of injury). Notably, a fourth component 1110 indicates a compartment that is substantial in the injured cords but is not present in the control cords, and is likely to reflect a microstructural change resulting from the injury. In addition, as can be seen from the composite images, the spatial maps for different components have considerable spatial overlap, which suggests that DR-CSI is successfully disentangling partial volume contributions from multiple tissue compartments within the same voxel, as would be expected based on the previous numerical simulation and phantom experiment results.

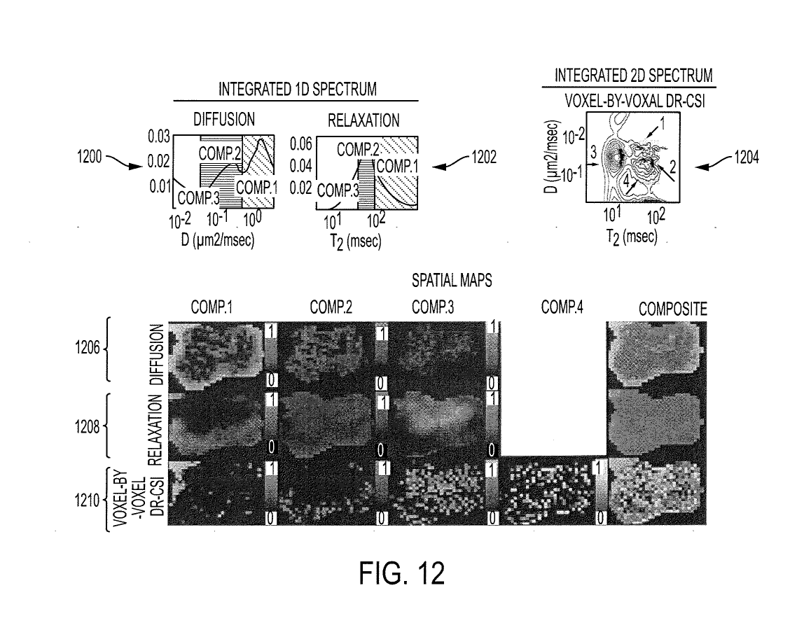

For comparison, FIG. 12 shows the compartment estimation results from conventional methods. There is considerable ambiguity in the 1D diffusion spectra 1200, 1206 and 1D relaxation spectra 1202, 1208, which resolve substantially fewer peaks than the DR-CSI spectra 1204, 1210. The voxel-by-voxel DR-CSI (without spatial regularization) results 1210 yields spectra with considerably less structure than the proposed approach, and yields spatial maps that are difficult to interpret in a meaningful way.

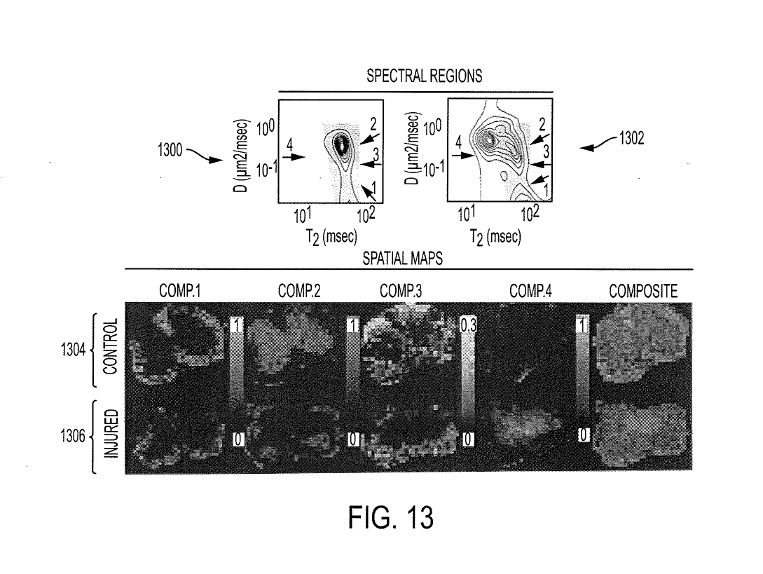

FIG. 13 illustrates spectral regions of a control spine 1300 and an injured spine 1302 using the DR-CSI method with a perpendicular diffusion orientation. The plots 1300, 1302 represent the spectral regions that are integrated to generate the spatial maps. The images 1304 illustrate the spatial maps corresponding to various components for the control spine 1304 and for the injured spine 1306.

The extensive simulation, phantom, and ex vivo mouse spinal cord results strongly confirm the hypothesis that DR-CSI can offer substantial advantages in resolving overlapping tissue compartments relative to traditional methods.

While DR-CSI was presented using a relatively simple 2D model involving a 1D diffusion coefficient and a 1D T₂ relaxation coefficient with contrast manipulated through the b value and the TE value, it is important to emphasize that this model was only assumed for the sake of providing a simple proof-of-principle demonstration of the power of the technique. It is straightforward to include more complicated data acquisition and biophysical compartment models that account for non-exponential signal variations, diffusion anisotropy, diffusion time dependence, water exchange, imperfect flip angles, B0 field inhomogeneity, etc.

It is also important to note that DR-CSI can potentially be used in a substantially broader range of settings than shown in previous illustrations. Alternative types of multidimensional spectral estimation are possible within this framework, including T₁−T₂, D−D, D−T₁, D−T₁−T₂. To enable such alternative types of multidimensional spectroscopic imaging, the signal model in Equation 6 may be generalized as shown in Equation 12 below:

m(r,γ)=∫∫ƒ(r,θ)k(γ,θ)dθ, Equation 12:

where r is the vector of spatial coordinates, m(r,γ) is the observed signal using experimental contrast parameters γ, ƒ(r,θ) is the multidimensional spectroscopic image as a function of contrast parameters θ, and k(γ,θ) is the ideal signal expected to be observed when using the contrast encoding parameters γ in the presence of the parameters θ. The signal model in Equation 12 can accommodate other contrast encoding mechanisms under various choices of γ (e.g., γ={b,TE}, {TI,TE}, {b,TI}, {b,TR}, {b,TI,TE}, etc.) and corresponding choices of θ (e.g., θ={D,T₁}, {T₁,T₂}, {T₁, T₂*}, {D,T₂}, {D,T₁,T₂}, etc.). In the signal model, it is also worth noting that k(γ,θ) is not required to be separable and exponential as it was in the diffusion-relaxation case from Equation 6. To estimate the spectroscopic image, the same estimation problem described in Equation 9 can be solved once the necessary changes have been made.

As an application example, T₁ relaxation-T₂ relaxation correlation spectroscopic imaging was implemented using a high-dimensional dataset where T₁ relaxation contrast and T₂ relaxation contrast were nonseparably encoded, which leads to the signal model in Equation 13 below:

m(x,y,TI,TE)=∫∫ƒ(x,y,T₁,T₂)(1−2e^{-TI/T}^{₁})e^{-TE/T}^{₂}dT₁dT₂, Equation 13:

where m (x,y,TI,TE) is the measured image with contrast encoding parameters TI (inversion time) and TE (echo time), and ƒ(x,y,T₁,T₂) is the spectroscopic image for T₁−T₂.

To demonstrate this approach, in vivo human brain data was acquired using an inversion recovery Carr-Pucell-Meiboom-Gill (CPMG) sequence on a 3T human MRI system (available under the brand name Achieve; available from Philips Healthcare, Best, The Netherlands) with 2 mm×2 mm in-plane-resolution, 4 mm slice thickness and TR=5000 ms. For simultaneous T₁ and T₂ contrast encoding, every combination of 7 inversion times (TI=0, 100, 200, 400, 700, 1000 and 2000 ms) and 15 echo times (from TE=22.5 ms to 217.5 ms in 15 ms increments) was used for a total of P=98 contrasts. For estimation, a dictionary K was constructed with Q=10,000 dictionary elements and optimization was performed using λ=0.01 and zero initialization.

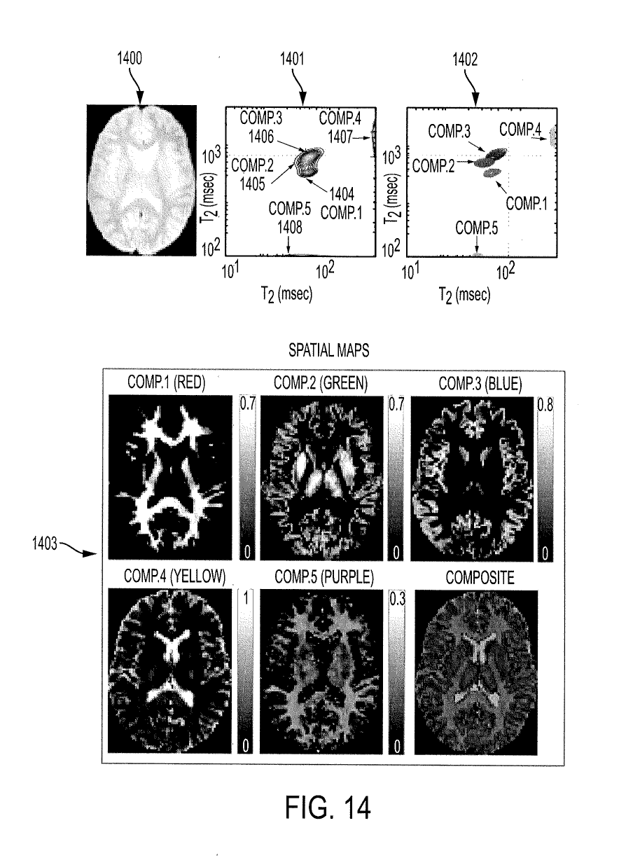

FIG. 14 illustrates an example image 1400 from a full dataset (TI=0 ms, TE=22.5 ms) and estimation results. As can be seen in the spatially-averaged spectrum 1401 and the representative five individual spectra 1402 which were plotted from different spatial locations, five resolved peaks were observed. Spatial maps of these peaks are shown in 1403. These five peaks closely match anatomical expectations: the first component 1404 seems to correspond to a part of white matter (WM); the second component 1405 seems to correspond to a mixture of WM and gray matter (GM); the third component 1406 seems to correspond to GM; the fourth component 1407 seems to correspond to cerebrospinal fluid (CSF); and the fifth component 1408 resembles the myelin water compartment. It is important to emphasize that the DR-CSI approach clearly separated out realistic-looking anatomical structures and revealed partial voluming of the associated structure, which is impossible with conventional 1D methods. The ability to identify five distinct compartments is a substantial performance improvement over previous 1D approaches based on T₂ spectra that usually only separate two or three compartments.

The present disclosure described and evaluated DR-CSI, a novel correlation spectroscopic imaging method that combines ideas from multidimensional correlation spectroscopy with imaging gradients and an advanced high-dimensional joint spatial-spectral estimation scheme. This disclosure demonstrates that DR-CSI has powerful capabilities for resolving spatially-overlapping tissue compartments using numerical simulations and several experimental datasets. It is expected that the DR-CSI technique, along with its future evolutions, may substantially expand the role of MRI in probing important features of tissue microstructure that have previously been inaccessible to traditional MR methods.

Exemplary embodiments of the methods/systems have been disclosed in an illustrative style. Accordingly, the terminology employed throughout should be read in a non-limiting manner. Although minor modifications to the teachings herein will occur to those well versed in the art, it shall be understood that what is intended to be circumscribed within the scope of the patent warranted hereon are all such embodiments that reasonably fall within the scope of the advancement to the art hereby contributed, and that that scope shall not be restricted, except in light of the appended claims and their equivalents.

What is claimed is:

1. A method for identifying and spatially mapping microenvironments using coarse-resolution correlation spectroscopic imaging comprising:
acquiring, using a magnetic resonance imaging (MRI) scanner, acquired data that includes high-dimensional contrast encoded data of a target for each of multiple voxels;
creating, using a signal processor, a model of the acquired data as a spatially-varying mixture of high dimensional real-valued exponential decays; and
estimating, using the signal processor, a multidimensional correlation spectroscopic image that includes a multidimensional correlation spectrum at each of the multiple voxels.

2. The method of claim 1 wherein the high-dimensional contrast encoded data includes two or more contrast encoding dimensions including a first contrast encoding dimension associated with diffusion or relaxation contrast and a second contrast encoding dimension associated with diffusion or relaxation contrast and having encoding that is performed using at least two of multiple diffusion weightings, multiple echo times, multiple repetition times, multiple inversion times, multiple flip angle values, or similar diffusion or relaxation contrast encoding parameters.

3. The method of claim 2 wherein creating the model of the acquired data includes an equation m(r,γ)=∫∫ƒ(r,θ)k(γ,θ) dθ, or a discretized approximation thereof, wherein:
m(r,γ) is the high-dimensional contrast encoded data at a vector of spatial coordinates r and at a set of contrast encoding parameters γ;
the contrast encoding parameters γ can be chosen from various MRI contrast mechanisms;
ƒ(r,δ) is the multidimensional spectroscopic image as a function of a contrast parameters θ corresponding to a choice of γ; and
k(γ,δ) is an ideal signal corresponding to the contrast encoding parameter γ and the contrast parameters θ.

4. The method of claim 3 wherein creating the model of the acquired data includes modeling the acquired data using an equation
$$m ( x , y , b , TE ) = \int \int f ( x , y , D , {T}_{2} ) {e}^{- bD} {e}^{\frac{TE}{{T}_{2}}} {dDdT}_{2} ,$$
or a discretized approximation thereof, wherein:
m(x,y,b,TE) is the high-dimensional contrast encoded data at a spatial location x, y, at a diffusion encoding value b, and at an echo time TE; and
ƒ(x,y,D,T₂) is a spatially-varying diffusion-relaxation correlation spectrum as a function of a diffusion coefficient D and a relaxation parameter T₂.

5. The method of claim 3 wherein creating the model of the acquired data includes an assumption that ƒ(r,θ) equals zero or a positive value and will exhibit smooth spatial variation.

6. The method of claim 2 further comprising providing spatial information corresponding to each of the microenvironments using the model of the acquired data via DR-CSI.

7. The method of claim 1 wherein creating the model of the acquired data includes solving a dictionary-based spatially-regularized nonnegative least squares optimization problem.

8. The method of claim 1 further comprising selecting more than two contrast mechanisms, wherein acquiring the high-dimensional contrast encoded data includes acquiring the high-dimensional contrast encoded data that is non-separably encoded with the multiple contrast mechanisms, and each of the multiple contrast mechanisms includes at least one dimension.

9. The method of claim 8 further comprising:
generating, by the signal processor, a spectroscopic image with a higher dimensional spectrum for each of the multiple voxels;
constructing, by the signal processor, spatial maps of peaks in the higher dimensional spectrum; and
outputting, by an output device, the spatial maps of the peaks.

10. A method for identifying microstructures using magnetic resonance imaging (MRI), comprising:
acquiring, using a MRI scanner, acquired data that includes multidimensional information about at least one of diffusion characteristics or relaxation characteristics for each of multiple locations along a spatial plane or in a spatial volume;
estimating, by a signal processor, a multidimensional correlation spectroscopic image that includes the at least one of the diffusion characteristics or the relaxation characteristics at each of the multiple locations; and
outputting, by an output device, the multidimensional correlation spectroscopic image that includes a multidimensional correlation spectrum at each of the multiple locations.

11. The method of claim 10 wherein the multidimensional correlation spectroscopic image has at least two spectroscopic dimensions including at least one of diffusion dimensions or relaxation dimensions at each of the multiple locations.

12. The method of claim 10 further comprising creating, using the signal processor, a model of the acquired data based on the acquired data, wherein estimating the multidimensional correlation spectroscopic image includes estimating the multidimensional correlation spectroscopic image using the model of the acquired data.

13. The method of claim 12 wherein the model of the acquired data includes a data consistency constraint, a non-negativity constraint, and a spatial regularization constraint.

14. The method of claim 12 wherein estimating the multidimensional correlation spectroscopic image includes estimating the multidimensional correlation spectroscopic image
$${\{ {\hat{f}}_{i} \}}_{i = 1}^{N} = {arg min}_{{\{ {f}_{i} \}}_{i = 1}^{N}} {\sum }_{i = 1}^{N} [ {t}_{i} \vert \vert {m}_{i} - {Kf}_{i} {\vert \vert}_{2}^{2} + {𝕀}_{+} ( {f}_{i} ) + {\sum }_{j ∈ Δ i} \vert \vert {f}_{j} - {f}_{i} {\vert \vert}_{2}^{2} ] ,$$
wherein {\hat{f}ᵢ}ᵢ₌₁^{N} represents the estimated multidimensional correlation spectroscopic image, i represents each voxel (each combination of an x location and a y location), mᵢ represents the acquired data at an i^{th} voxel, K is a matrix representing a decaying signal, fᵢ represents the estimated multidimensional correlation spectrum at an i^{th} voxel, and tᵢ represents constants to avoid fitting the multidimensional correlation spectra to noise-only voxels of the image.

15. The method of claim 10 wherein acquiring the acquired data includes acquiring two-dimensional MRI images with at least one of varying relaxation encoding parameters to encode relaxation characteristics or varying diffusion encoding parameters to encode diffusion characteristics, resulting in a nonseparable high-dimensional contrast encoding at each voxel of the images.

16. A system for identifying microstructures using magnetic resonance imaging (MRI), comprising:
a MRI scanner configured to perform MRI scans;
a MRI controller coupled to the MRI scanner and configured to control the MRI scanner to acquire a dataset that includes data by simultaneously varying at least two encoding parameters at multiple locations, the at least two encoding parameters including at least one of a relaxation contrast encoding parameter or a diffusion contrast encoding parameter; and
a signal processor coupled to the MRI scanner and configured to create a model of the dataset and to estimate a multidimensional correlation spectroscopic image that includes a multidimensional correlation spectrum for each of the multiple locations.

17. The system of claim 16 further comprising an output device configured to output data, wherein the signal processor is further configured to:
generate a spectroscopic image with a higher dimensional spectrum for each of the multiple locations;
construct spatial maps of peaks in the higher dimensional spectrum; and
control the output device to output the spatial maps of the peaks.

18. The system of claim 16 wherein the signal processor is further configured to create the model using an equation m(r,γ)=∫∫ƒ(r,θ)k(γ,θ)dθ, or a discretized approximation thereof, wherein:
m(r,γ) is high-dimensional contrast encoded data at a vector of spatial coordinates r and at a set of contrast encoding parameters γ;
the contrast encoding parameters γ can be chosen from various MRI contrast mechanisms;
ƒ(r,θ) is the multidimensional correlation spectroscopic image as a function of contrast parameters θ corresponding to a choice of γ; and
k(γ,θ) is an ideal signal corresponding to the contrast encoding parameter γ and the contrast parameters θ.

19. The system of claim 18 wherein the signal processor is configured to create the model using an equation
$$m ( x , y , b , TE ) = \int \int f ( x , y , D , {T}_{2} ) {e}^{- bD} {e}^{\frac{TE}{{T}_{2}}} {dDdT}_{2} ,$$
or a discretized approximation thereof, wherein:
m(x,y,b,TE) is the dataset at a spatial location x, y, at a diffusion encoding value b, and at an echo time TE; and
ƒ(x,y,D,T₂) is a spatially-varying diffusion-relaxation correlation spectrum as a function of a diffusion coefficient D and a relaxation parameter T₂.

20. The system of claim 18 wherein the signal processor is further configured to create the model using an assumption that ƒ(r,θ) equals zero or a positive value and will exhibit smooth spatial variation.
